(19) United States
(12) Patent Application Publication
(10) Pub. No.: US 2016/0071700 A1
(43) Pub. Date: Mar. 10, 2016

(54) PLASMA PROCESSING APPARATUS AND CLEANING METHOD

(71) Applicant: TOKYO ELECTRON LIMITED, Tokyo (JP)

(72) Inventor: Toshihisa NOZAWA, Miyagi (JP)

(73) Assignee: TOKYO ELECTRON LIMITED, Tokyo (JP)

(21) Appl. No.: 14/846,083

(22) Filed: Sep. 4, 2015

(30) Foreign Application Priority Data
Sep. 9, 2014 (JP) 2014-183425

(51) Int. Cl. H01J 37/32

(52) U.S. Cl. CPC H01J 37/3288; H01J 37/3244; H01J 37/32715

(57) ABSTRACT

Disclosed is a plasma processing apparatus that turns a processing gas into plasma so as to process a substrate. The plasma processing apparatus includes: a processing container configured to hermetically accommodate a substrate therein; a placement table installed on a bottom surface of the processing container, and configured to place the substrate thereon; a gas supply mechanism configured to supply at least one of a processing gas and a purge gas to an inside of the processing container through a gas supply pipe; a plasma generating mechanism configured to generate plasma of the processing gas within the processing container; an exhaust mechanism configured to exhaust the inside of the processing container through an exhaust pipe; and an ultrasonic vibration generating mechanism configured to apply ultrasonic vibration to a corner portion within the processing container.

### CROSS-REFERENCE TO RELATED APPLICATIONS

This application is based on and claims priority from Japanese Patent Application No. 2014-183425, filed on Sep. 9, 2014, with the Japan Patent Office, the disclosure of which is incorporated herein in its entirety by reference.

### TECHNICAL FIELD

The present disclosure relates to a plasma processing apparatus that performs a plasma processing on a substrate as a processing target object, and a cleaning method performed in the plasma processing apparatus.

### BACKGROUND

In manufacturing a semiconductor device, processings of forming various films including an insulation film or etching processings for films such as, for example, the insulation film are performed in a decompressed processing container provided in a substrate processing apparatus such as, for example, a plasma processing apparatus. Within such a decompressed processing container, for example, a reaction product, produced by sputtering using plasma generated within the processing container or by reactive gases, is attached and forms a film. In addition, when the film thickness of the film, derived from the reaction product attached to the inside of the processing container, reaches, for example, about several μm, the film is partially peeled off by the stress applied thereto due to, for example, gas flow within the processing container, and is turned into fine particles to be scattered.

When such particles are attached to a substrate, a product yield is reduced. For that reason, high cleanliness is required for the substrate processing apparatus.

As a cleaning method for cleaning the inside of a processing container, for example, Japanese Patent Laid-Open Publication No. 2005-197467 proposes generating plasma of a cleaning gas containing, for example, fluorine gas, within the processing container so as to remove a reaction product attached to the inside of the processing container by the plasma.

### SUMMARY

In order to achieve the objects described above, the present disclosure provides a plasma processing apparatus that turns a processing gas into plasma so as to process a substrate. The plasma processing apparatus includes: a processing container configured to hermetically accommodate a substrate therein; a placement table installed on a bottom surface of the processing container, and configured to place the substrate thereon; a gas supply mechanism configured to supply at least one of a processing gas and a purge gas to an inside of the processing container through a gas supply pipe; a plasma generating mechanism configured to generate plasma of the processing gas within the processing container; an exhaust mechanism configured to exhaust the inside of the processing container through an exhaust pipe; and an ultrasonic vibration generating mechanism configured to apply ultrasonic vibration to a corner portion within the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical sectional view illustrating a schematic configuration of a plasma processing apparatus according to an exemplary embodiment.

FIG. 2 is a horizontal sectional view illustrating a schematic arrangement of an ultrasonic vibration generating mechanism.

FIG. 3 is a vertical sectional view illustrating a state in which a reaction product is attached in the vicinity of corner portions within a processing container.

FIG. 4 is a vertical sectional view illustrating a state in which a reaction product attached in the vicinity of corner portions within a processing container is peeled off.

FIG. 5 is a vertical sectional view illustrating a schematic arrangement of an ultrasonic vibration generating mechanism according to another exemplary embodiment.

FIG. 6 is a vertical sectional view illustrating a schematic arrangement of an ultrasonic vibration generating mechanism according to still another exemplary embodiment.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

Even if the inside of the processing container were cleaned using, for example, the plasma of a cleaning gas, for example, it was impossible to completely remove the reaction product attached to the inside of the processing container, and it was difficult to suppress the generation of particles within the processing container. Thus, in some cases, together with the above-described cleaning method, for example, a cleaning method so-called a cycle purging was used in which a high voltage is applied while causing a purge gas to flow within the processing container so as to scatter particles by electromagnetic stress. However, it was also difficult to completely remove the reaction product attached to the inside of the processing container. Thus, under this circumstance, the inside of the processing container is kept clean by a so-called wet cleaning in which the processing container is periodically released to the air and the inside of the processing container is cleaned using, for example, a cloth.

However, when the processing container is released to the air, several days are usually required until the substrate processing apparatus is restored to an operable state after the wet cleaning. As a result, there is a problem in that the operation rate of the substrate processing apparatus is considerably degraded. Therefore, what is requested is a method of keeping the inside of the processing container clean without performing the wet cleaning.

Accordingly, the inventor of the present application has carefully investigated the locations where a reaction product film was attached and the components of the film at the time of performing a wet cleaning. As a result, it has been found that the film was intensively attached at the corner portions within the processing container, and the components of the film may also include the fluorine contained in the cleaning gas, in addition to the components derived from the processing gas. Here, the corner portions include, for example, a recessed portion within the processing container, in addition to a portion formed by overlapping planes such as, for example, a portion formed between the ceiling and the side wall of the processing container. In addition, the inventor has carefully reviewed the reasons why the reaction product derived from the processing gas or the fluorine containing film is attached to the corner portions, and has found the following two points as estimated reasons. As the first reason, it is considered that, since a gas tends to stay in the vicinity of the corner portions including the recessed portions and the plasma of the cleaning gas does not sufficiently reach the corner portions, the corner portions are not sufficiently cleaned. As the second reason, it is considered that the fluorine containing reaction product is easily attached to a location where a gas flow is stagnant since the fluorine containing reaction product is non-volatile. Accordingly, the inventor has obtained an idea that the number of times of performing the wet cleaning may be reduced if the reaction product in the corner portions is capable of being removed.

The present disclosure has been made based on this idea, and an object of the present disclosure is to efficiently peel off a film attached to a corner portion within a processing container of a plasma processing apparatus.

In order to achieve the object described above, the present disclosure provides a plasma processing apparatus that turns a processing gas into plasma so as to process a substrate. The plasma processing apparatus includes: a processing container configured to hermetically accommodate a substrate therein; a placement table installed on a bottom surface of the processing container, and configured to place the substrate thereon; a gas supply mechanism configured to supply at least one of a processing gas and a purge gas to an inside of the processing container through a gas supply pipe; a plasma generating mechanism configured to generate plasma of the processing gas within the processing container; an exhaust mechanism configured to exhaust the inside of the processing container through an exhaust pipe; and an ultrasonic vibration generating mechanism configured to apply ultrasonic vibration to a corner portion within the processing container.

According to the present disclosure, since the ultrasonic vibration generating mechanisms are provided to apply ultrasonic vibration to a corner portion within the processing container, a film attached to the corner portion within the processing container can be efficiently peeled off, and the peeled film can be rapidly exhausted by the exhaust mechanism. In addition, since the purge gas is supplied through the gas supply pipe so as to perform a gas purging, the peeled film can be rapidly exhausted from the inside of the processing container. Accordingly, the inside of the processing container can be kept clean and the number of times of performing a wet cleaning can be reduced.

The gas supply pipe may be provided above the placement table, and the exhaust pipe may be provided below the substrate placed on the placement table. The ultrasonic vibration generating mechanism may be placed outside the processing container so as to apply the ultrasonic vibration to a corner portion between the gas supply pipe and the exhaust pipe within the processing container. In such a case, the gas supply pipe may be provided in a central portion of the processing container and above the placement table.

The plasma processing apparatus may further include: a controller that is configured: to control the plasma generating mechanism to stop plasma generation within the processing container after terminating a processing of the substrate; to control the vibration generating mechanism to apply ultrasonic vibration to the corner portion after stopping the plasma generation; and to control the gas supply mechanism to supply a purge gas to the inside of the processing container during the applying of the ultrasonic vibration.

The controller may be configured to control the gas supply mechanism and the ultrasonic vibration generating mechanism to stop the supplying of the purge gas and the applying of the ultrasonic vibration after a first predetermined time period elapses from the applying of the ultrasonic vibration, and to perform the supplying of the purge gas and the applying of the ultrasonic vibration again after a second predetermined time period elapses from the stopping of the supplying of the purge gas and the applying of the ultrasonic vibration.

The controller may be configured to control the gas supply mechanism and the ultrasonic vibration generating mechanism to repeatedly perform the supplying of the purge gas and the stopping thereof, and the applying of the ultrasonic vibration and the stopping thereof.

The exhaust pipe may be provided with a particle monitor that is configured to measure the number of particles exhausted through the exhaust pipe, and the controller may be configured to stop the applying of the ultrasonic vibration when the number of particles measured by the particle monitor per unit time is less than a predetermined value.

According to another aspect, the present disclosure provides a method of cleaning an inside of a processing container in a plasma processing apparatus that turns a processing gas into plasma so as to process a substrate within the processing container. The cleaning method includes: supplying the processing gas to the inside of the processing container to generate the plasma of the processing gas, and stopping the supplying of the processing gas and the generating of the plasma after performing a plasma processing on the substrate placed on a placement table within the processing container; and after the substrate is carried out from the processing container, applying ultrasonic vibration to a corner portion within the processing container and supplying a purge gas into the inside of the processing container during the applying of the ultrasonic vibration.

The supplying of the purge gas may be performed through a gas supply pipe provided above the placement table, the inside of the processing container may be exhausted through an exhaust pipe provided below the substrate placed on the placement table, and the ultrasonic vibration may be applied by an ultrasonic vibration generating mechanism placed outside the processing container so as to apply the ultrasonic vibration to a corner portion between the gas supply pipe and the exhaust pipe within the processing container. In such a case, the gas supply pipe may be provided installed in a central portion of the processing container and above the placement table.

The supplying of the purge gas and the applying of the ultrasonic vibration may be stopped after a first predetermined time period elapses from the applying of the ultrasonic vibration, and the supplying of the purge gas and the applying of the ultrasonic vibration again may be performed after a second predetermined time period elapses from the stopping of the supplying of the purge gas and the applying of the ultrasonic vibration.

The supplying of the purge gas and the stopping thereof, and the applying of the ultrasonic vibration and the stopping thereof may be repeatedly performed.

The number of particles exhausted through the exhaust pipe may be measured by a particle monitor provided in the exhaust pipe, and the applying of the ultrasonic vibration may be stopped when the number of particles measured by the particle monitor per unit time is less than a predetermined value.

According to the present disclosure, a film attached to a corner portion within a processing container can be efficiently peeled off, and the peeled film can be rapidly exhausted by simultaneously performing a gas purging, the peeled film can be rapidly exhausted from the inside of the processing container. Accordingly, the inside of the processing container can be kept clean.

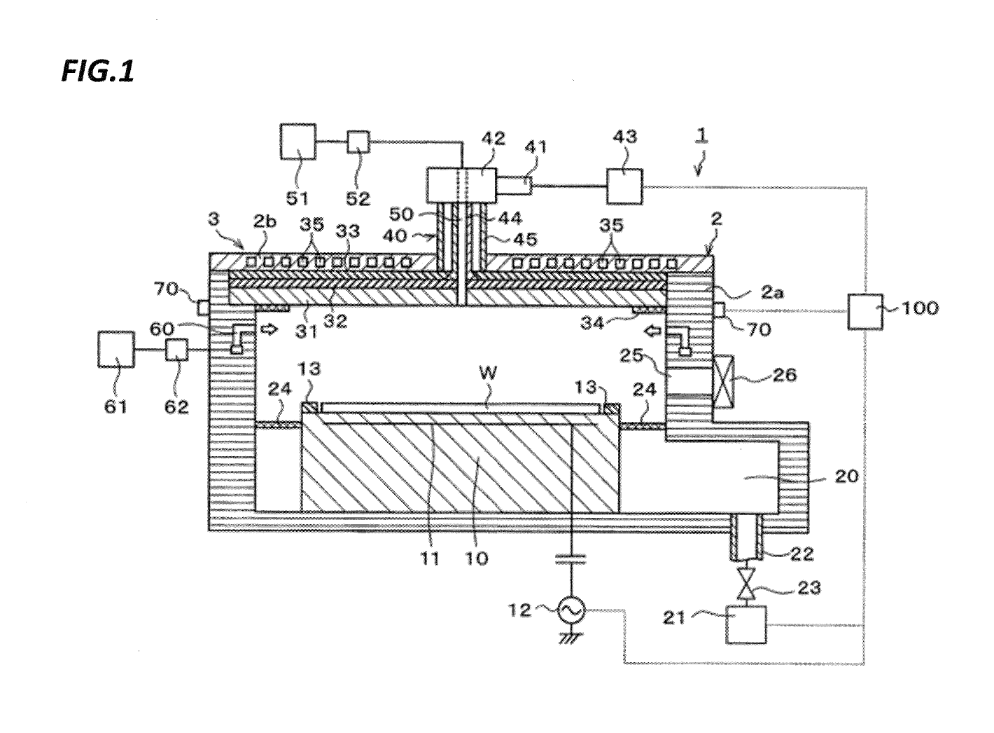

Hereinafter, exemplary embodiments of the present disclosure will be described. FIG. 1 is a vertical sectional view schematically illustrating a configuration of a plasma processing apparatus 1 according to an exemplary embodiment of the present disclosure. In addition, descriptions will be made on a case where the plasma processing apparatus 1 of the present disclosure performs a plasma chemical vapor deposition (CVD) processing on a surface of a wafer W as a processing target object so as to form a SiN film (silicon nitride film) on the surface of the wafer W, by way of an example. In the specification and drawings, the constituent elements having the substantially equal functions will be denoted by the same symbols, and duplicate descriptions thereof will be omitted.

The plasma processing apparatus 1 includes a processing container 2, of which the inside is hermetically maintained, and a radial line slot antenna 3 configured to supply microwaves for plasma generation to the inside of the processing container 2. The processing container 2 includes a top-opened main body 2a having a substantially cylindrical shape, and a cover 2b having a substantially disc shape and configured to hermetically close the opening of the main body 2a. The main body 2a and the cover 2b are formed of a metal such as, for example, aluminum, and a protection layer (not illustrated) is sprayed on the surfaces thereof. The protection layer is formed of, for example, yttrium oxide (Y₂O₃) that is highly plasma-resistant. In addition, the main body 2a is grounded via a ground line (not illustrated).

On the bottom surface of the main body 2a of the processing container 2, a susceptor 10 is provided so as to place a wafer W thereon. The susceptor 10 has, for example, a disc shape, and is formed of a metal such as, for example, aluminum. An electrode 11 is embedded in the susceptor 10, and a power supply 12 is connected to the electrode 11 so as to apply a voltage for attracting and holding the wafer W. In addition, the power supply 12 is configured to be capable of alternately applying a high voltage of for example, ±1 kV, to the electrode 11. Thus, the particles attached to the inside of the processing container 2 can be scattered by intermittently applying the high voltage by the power supply 12 so as to generate electromagnetic stress within the processing container 2. In addition, a high frequency power supply for bias (not illustrated) is connected to the susceptor 10 via a matcher (not illustrated). The high frequency power supply outputs high frequency waves having a predetermined frequency that is suitable for controlling the energy of ions drawn to the wafer W, for example, high frequency waves of 13.56 MHz. In addition, although not illustrated, a heater may be installed inside the susceptor 10 so as to heat the wafer W to a predetermined temperature.

In addition, below the susceptor 10, a lift pin (not illustrated) is provided so as to support and move up and down the wafer W from the bottom side of the wafer W. The lift pin is inserted through a through hole (not illustrated) formed in the susceptor 10 to be capable of protruding from the top surface of the susceptor 10.

On the top surface of the susceptor 10, an annular focus ring 13 is provided to surround the wafer W. The focus ring 13 is made of an insulative material such as, for example, ceramic or quartz. The plasma generated within the processing container 2 converges on the wafer W by the action of the focus ring 13, and as a result, the in-plane plasma processing uniformity of the wafer W is improved.

In the bottom portion of the main body 2a of the processing container 2, an exhaust chamber 20 is formed, for example, to laterally protrude from the main body 2a. To the bottom of the exhaust chamber 20, an exhaust mechanism 21 is connected via an exhaust pipe 22 so as to exhaust the inside of the processing container 2. An adjustment valve 23 is provided in the exhaust pipe 22 so as to adjust the exhaust amount through the exhaust mechanism 21.

On the top side of the exhaust chamber 20, an annular baffle plate 24 is provided along the outer surface of the susceptor 10 and the inner surface of the main body 21 so as to uniformly exhaust the inside of the processing container 2. The baffle plate 24 includes openings (not illustrated) that are formed over the entire circumference thereof to penetrate the baffle plate 24 in the thickness direction.

A carry-in/out port 25 for a wafer W is formed through the side wall of the main body 2a of the processing container 2 above the baffle plate 24. In the carry-in/out port 25, a gate valve 26 configured to be capable of being opened/closed is installed so that when the gate valve 26 is closed, the inside of the processing container 2 is hermetically sealed.

In the opening of the ceiling of the processing container 2, a radial line slot antenna 3 is installed to supply microwaves for plasma generation to the inside of the processing container 2. The radial line slot antenna 3 includes a microwave transmission plate 31, a slot plate 32, and a slow wave plate 33. The microwave transmission plate 31, the slot plate 32, and the slow wave plate 33 are stacked in this order from the bottom, and the microwave transmission plate 31 is supported by an annular support member 34 installed to inwardly protrude from the vicinity of the opening of the main body 2a of the processing container 2. Similarly to the processing container 2, the support member 34 is formed of a metal such as, for example, aluminum, and a protection layer (not illustrated) is sprayed on the surface of the support member 34. The protection layer is made of, for example, yttrium oxide (Y₂O₃) that is highly plasma-resistant. A gap between the microwave transmission plate 31 and the support member 34 is kept hermetically by, for example, a seal material such as an O-ring (not illustrated). For the microwave transmission plate 31, a dielectric material such as, for example, quartz, Al₂O₃, or AlN, is used, and the microwave transmission plate 31 transmits microwaves. In addition, the top surface of the slow wave plate 33 is covered by the cover 2b.

A plurality of slots are formed in the slot plate 32 mounted on the top surface of the microwave transmission plate 31, and the slot plate 32 serves as an antenna. For the slot plate 32, a conductive material such as, for example, copper, aluminum, or nickel, is used.

The slow wave plate 33 mounted on the top surface of the slot plate 32 is formed of a low loss dielectric material such as, for example, quartz, Al₂O₃, or AlN, and the slow wave plate 33 shortens the wavelength of microwaves.

The cover 2b that covers the top surface of the slow wave plate 33 includes a plurality of annular flow paths 35 provided therein so as to allow a cooling medium to flow therethrough. By the cooling medium flowing in the flow paths 35, the cover 2b, the microwave transmission plate 31, the slot plate 32, and the slow wave plate 33 are controlled to a predetermined temperature.

A coaxial waveguide 40 is connected to the central portion of the cover 2b. To the upper end of the coaxial waveguide 40, a microwave generating source 43 is connected via a rectangular waveguide 41 and a mode converter 42. The microwave generating source 43 is installed outside the processing container 2, and may generate microwaves of, for example, 2.45 GHz.

The coaxial waveguide 40 includes an inner conductor 44 and an outer pipe 45. The inner conductor 44 is connected with the slot plate 32. The slot plate 32 side of the inner conductor 44 is formed in a conical shape so as to allow the microwaves to be efficiently propagated to the slot plate 32.

With this configuration, the microwaves generated from the microwave generating source 43 are sequentially propagated to the inner portions of the rectangular waveguide 41, the mode converter 42, and the coaxial waveguide 40, and compressed in the slow wave plate 33 so that the wavelength of the microwaves is shortened. Then, circularly polarized microwaves from the slot plate 32 are transmitted through the microwave transmission plate 31 to be irradiated to the inside of the processing container 2. By the microwaves, a processing gas is turned into plasma within the processing container 2, and a plasma processing is performed on a wafer W by the plasma.

In addition, in the present exemplary embodiment, the radial line slot antenna 3, the coaxial waveguide 40, the rectangular waveguide 41, the mode converter 42, and the microwave generating source 43 constitute a plasma generating mechanism in the present disclosure.

In the central portion of the ceiling of the processing container 2, i.e., in the central portion of the radial line slot antenna 3, a first gas supply pipe 50 is installed. The first gas supply pipe 50 penetrates the radial line slot antenna 3 in the vertical direction, and one end of the first gas supply pipe 50 is opened on the bottom surface of the microwave transmission plate 31. In addition, the first gas supply pipe 50 penetrates the inside of the inner conductor 44 of the coaxial waveguide 40 and is inserted into the inside of the mode converter 42. The other end of the first gas supply pipe 50 is connected to the first gas supply source 51.

Within the first gas supply source 51, a processing gas, a purge gas, and a cleaning gas are individually stored. As the processing gas, each of, for example, trisilyl amine (TSA), N₂ gas, H₂ gas, and Ar gas, is individually stored. Among them, TSA, N₂ gas, and H₂ gas are raw gases for forming a SiN film, and Ar gas is a gas for plasma excitation. In the following, the processing gas may be referred to as a “first processing gas.” As the purge gas, for example, nitrogen gas is stored. In the following, the purge gas may be referred to as a “first purge gas.” As the cleaning gas, for example, CF₄ gas, is stored. In the following, the cleaning gas may be referred to as a “first cleaning gas.”

The first gas supply pipe 50 is provided with a supply device group 52 including, for example, a valve or a flow rate control unit that controls the gas flow within the first gas supply pipe 50. The first processing gas or the first cleaning gas supplied from the first gas supply source 51 is supplied to the inside of the processing container 2 through the first gas supply pipe 50, and flows vertically downward toward the wafer W placed on the susceptor 10.

In addition, as illustrated in FIG. 1, a second gas supply pipe 60 is installed on the inner circumferential surface of the upper portion of the processing container 2. A plurality of second gas supply pipes 60 are provided at regular intervals along the inner circumferential surface of the processing container 2. A second gas supply source 61 is connected to the second gas supply pipes 60. Within the second gas supply source 61, for example, each of TSA, N₂ gas, H₂ gas, and Ar gas is individually stored as a processing gas. In the following, the processing gas may be referred to as a “second processing gas.” As the purge gas, for example, nitrogen gas is stored. In the following, the purge gas may be referred to as a “second purge gas.” As the cleaning gas, for example, CF₄ gas is stored. In the following, the cleaning gas may be referred to as a “second cleaning gas.”

The second gas supply pipe 60 is provided with a supply device group 62 including, for example, a valve or a flow rate control unit that controls the gas flow within the second gas supply pipe 62. The second processing gas or the second cleaning gas supplied from the second gas supply source 61 is supplied to the inside of the processing container 2 through the second gas supply pipe 60, and flows toward the outer circumference of the wafer W placed on the susceptor 10. In this way, the gases from the first gas supply pipe 50 are supplied toward the central portion of the wafer, and the gases from the second gas supply pipe 60 are supplied toward the outer circumference of the wafer W.

In addition, the gases, which are respectively supplied from the first gas supply pipe 50 and the second gas supply pipe 60 to the inside of the processing container 2, may be the same kind of gases or different kinds of gases, and each of the gases may be supplied at an independent flow rate or at an arbitrary flow rate ratio.

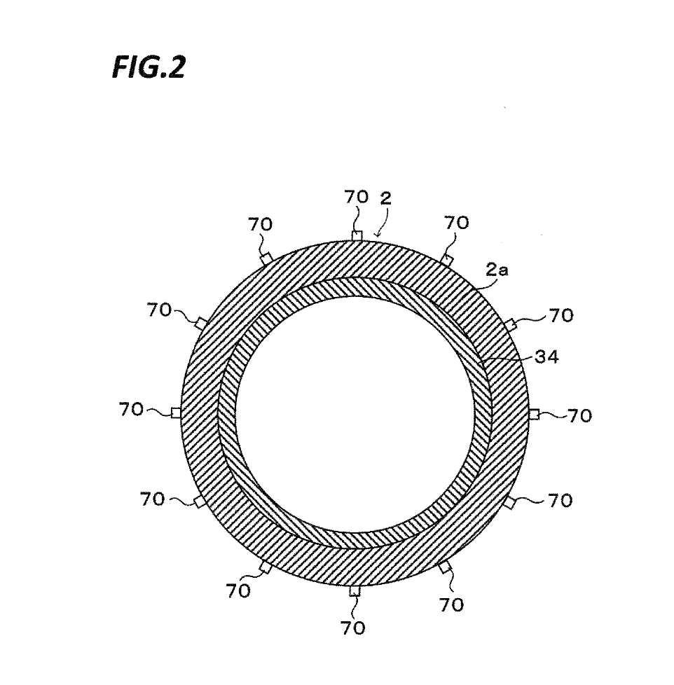

As illustrated in FIG. 1, on the outer surface of the main body 2a of the processing container 2, a plurality of ultrasonic vibration generating mechanisms 70 configured to apply ultrasonic vibration to the processing container 2 are installed at a height position which is approximately the same as that of the support member 34. The plurality of ultrasonic vibration generating mechanisms 70 are arranged, for example, at regular intervals over the entire circumference of the outer surface of the main body 2a, for example, as illustrated in FIG. 2. As the ultrasonic vibration generating mechanisms 70, well-known ultrasonic vibrators may be used. In addition, the frequency and power of the vibration generated by the ultrasonic vibration generating mechanisms 70 may be about 1 kHz or more and about 10 W or more, respectively, and more specifically, in a range of about 10 kHz to about 1 MHz, and about 20 W to about 100 W, respectively.

Each of the ultrasonic vibration generating mechanisms 70 is connected to a controller 100 to be described below, and subjected to the control of the controller 100 in terms of applying of ultrasonic vibration.

The plasma processing apparatus 1 described above is provided with the controller 100, as illustrated in FIG. 1. The controller 100 is, for example, a computer, and includes a program storage unit (not illustrated). In the program storage unit, programs are stored to control devices such as, for example, the above-mentioned ultrasonic vibration generating mechanisms 70, the microwave generating source 43, and each of the gas supply sources 51 and 61 so as to implement a plasma processing or a cleaning method to be described below in the plasma processing apparatus 1. In addition, the programs may be those recorded in a computer-readable record medium such as, for example, a computer-readable hard disc (HD), a flexible disc (FD), a compact disc (CD), a magneto optical (MO) disc, or a memory card, and installed in the controller 100 from the record medium.

The plasma processing apparatus 1 according to the present exemplary embodiment is configured as described above. Next, descriptions will be made on a plasma processing of a wafer which is performed in the plasma processing apparatus 1 according to the present exemplary embodiment, and a cleaning method within the processing container 2. In the present exemplary embodiment, descriptions will be made on a case where a plasma film-formation processing is performed on a wafer W as described above so as to form a SiN film on the surface of the wafer W.

In the processing of the wafer W, first, the gate valve 26 installed on the side surface of the main body 2a of the processing container 2 is opened, and the wafer W is carried into the processing container 2 through the carry-in/out port 25. The wafer W is placed on the susceptor 10 via the lift pins. At the same time, a DC voltage is applied to the electrostatic chuck, and the wafer W is electrostatically attracted to the susceptor 10 by Coulomb force. Then, the gate valve 26 is closed, the inside of the processing container 2 is hermetically sealed, and the exhaust mechanism 21 is operated so that the inside of the processing container 2 is decompressed to a predetermined pressure of, for example, 400 mTorr (=53 Pa).

Thereafter, the first processing gas is supplied to the inside of the processing container 2 from the first gas supply pipe 50, and the second processing gas is supplied to the inside of the processing container 2 from the second gas supply pipe 60. At this time, the flow rate of Ar gas supplied from the first gas supply pipe 50 is, for example, 100 sccm (mL/min), and the flow rate of Ar gas supplied from the second gas supply pipe 60 is, for example, 750 sccm (mL/min)

Simultaneously with supplying the first processing gas and the second processing gas into the processing container 2, the microwave generating source 43 is operated so that microwaves of a predetermined power is generated with a frequency of, for example, 2.45 GHz, in the microwave generating source 43. The microwaves are irradiated to the inside of the processing container 2 through the rectangular waveguide 41, the mode converter 42, the coaxial waveguide 40, and the radial line slot antenna 3. By the microwaves, the processing gases are turned into plasma within the processing container 2, dissociation of the processing gases progresses in the plasma, and a SiN film is formed on the surface of the wafer W by radicals (active species) generated at that time.

In addition, while the plasma processing is being performed on the wafer W, high frequency waves of a predetermined power are applied to the susceptor 10 with a predetermined frequency of, for example, 13.56 MHz, by a high frequency power supply (not illustrated). An RF bias applied in a proper range causes ions in the plasma to be drown into the wafer so that denseness of the SiN film is improved and traps in the film are increased.

Thereafter, when the SiN film is grown so that a predetermined film thickness of the SiN film is fanned on the wafer W, the supplying of the first processing gas and the second processing gas, and the irradiation of microwaves are stopped. Thereafter, the wafer W is carried out from the processing container 2, and a series of plasma processings are terminated.

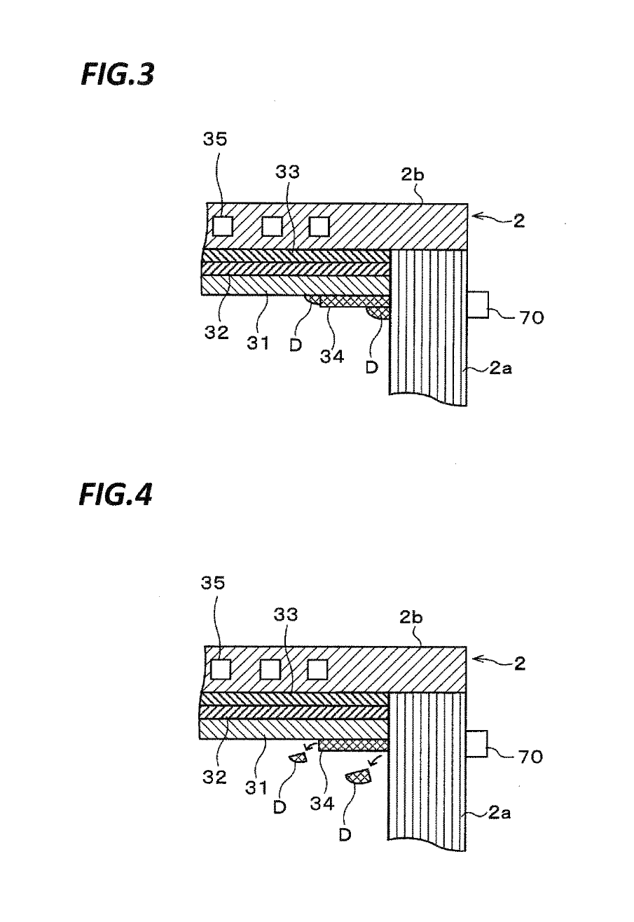

When the above-mentioned plasma processings are repeatedly performed, a film of a reaction product gradually is attached to the processing container 2. For this reason, for example, whenever a processing for a predetermined number of wafers W is completed, the first cleaning gas and the second cleaning gas are supplied to the inside of the processing container 2. At the same time, microwaves are irradiated and plasma of the cleaning gases are generated within the processing container 2 so that cleaning by the plasma is performed for a predetermined time period and as a result, the film derived from the reaction product and attached to the inside of the processing container 2 is removed. However, as described above, since the gases easily stay, for example, in the corner portions between the ceiling and side walls of the processing container 2 as illustrated in FIG. 3 (in the present exemplary embodiment, the corner portions between the bottom surface of the microwave transmission plate 31 and the inner circumferential surface of the support member 34 or the corner portions between the bottom surface of the support member 34 and the inner surface of the main body 2a), and the plasma of the cleaning gases do not sufficiently reach the corner portions, removal of the reaction product D is not sufficiently performed and thus, the reaction product D is deposited. In addition, a product produced by the reaction between the cleaning gases and the processing gases such as, for example, SiF, is not volatile, and thus, is also attached to the corner portions in which the gases easily stay. In addition, the reaction product D include at least one of the reaction product derived from the processing gases and the reaction product derived from the cleaning gases.

Accordingly, the cleaning method according to the present disclosure is performed after the plasma of the cleaning gases is generated within the processing container 2. In performing the cleaning according to the present invention, first, the supplying of cleaning gases and the irradiation of microwaves are stopped. Subsequently, the supplying of first purge gas and the second purge gas into the processing container 2 is started at a flow rate of, for example, 2 L/min (2000 sccm). Due to the introduction of the large flow rate of the purge gases, shock waves are generated within the processing container 2 so that the reaction product D physically attached to the inside of the processing container 2 is scattered. The scattered reaction product D is discharged from the exhaust pipe 22. However, at this time point, the reaction product D attached and deposited in the corner portions remain without being removed.

Accordingly, in parallel with the supplying of the first purge gas and the second purge gas, each of the ultrasonic vibration generating mechanisms 70 is activated by the controller 100, and applies ultrasonic vibration (e.g., frequency: 40 kHz, power: 50 W) to the processing container 2. At this time, since each of the ultrasonic vibration generating mechanisms 70 is installed at a height position which is approximately the same as that of the support member 34, the ultrasonic vibration is imparted to the corner portions within the processing container 2. Therefore, the reaction product D deposited and attached to the corner portions as illustrated in FIG. 4, is peeled off from the processing container 2. In addition, the peeled reaction product D is exhausted from the exhaust pipe 22 by being entrained in the flows of the first and second purge gases.

Thereafter, when the ultrasonic vibration is applied for a predetermined time period, for example, 2 to 20 sec, the applying of the ultrasonic vibration by each of the ultrasonic vibration generating mechanisms 70 and the supplying of the first and second purge gases are stopped by the controller 100. Thereafter, a high voltage is intermittently applied to the electrode by the power supply 12 and, at the same time, the purge gases are supplied again so as to perform a cycle purging by electromagnetic stress. In addition, the purge gases may be continuously supplied. As a result, the reaction product D, which have been peeled off by the ultrasonic vibration and then attached again to the inside of the processing container 2 after having been peeled off, or the reaction product D, which has been attached to an area other than the corner portions within the pressing container 2 but has not been completely peeled off by the cleaning gases or the purge gases, is scattered. The scattered reaction product D is exhausted from the exhaust pipe 22 by being entrained in the flow of the first and second purge gases.

Thereafter, when the applying of the high voltage is repeated by a predetermined number of times, the supplying amount of the first and second purge gases is reduced, and then, the discharge of the reaction product D from the processing container 2 is continued. Thereafter, the supplying of the first and second purge gases is stopped, and the cleaning within the processing container 2 is completed.

Thereafter, a new wafer W is carried into the processing container 2 and a plasma processing is performed thereon. In addition, when the processing of the wafer W is terminated, the wafer W is carried out from the processing container 2. In addition, when the plasma processing of the wafer W is repeatedly performed by a predetermined number of times, the cleaning by the cleaning gases, the cleaning by the purge gases and the ultrasonic vibration, and the cleaning by the applying of a high voltage are performed, and a series of such processes are repeatedly performed.

According to the foregoing exemplary embodiment, since the ultrasonic vibration generating mechanisms 70 are provided to apply ultrasonic vibration to the corner portions within the processing container 2, the film or particles of the reaction product D attached to the corner portions within the processing container 2 can be efficiently peeled off and scattered, and the scattered film or particles can be rapidly exhausted by the exhaust mechanism 21. Accordingly, as compared to a case of performing the conventional cleaning by a cleaning gas or the cleaning using cycle purging, the inside of the processing container 2 can be kept clean and the number of times of performing the wet cleaning can be reduced.

In the foregoing exemplary embodiment, the ultrasonic vibration is applied while supplying the first and second purge gases. However, it is sufficient if, for example, the first purge gas is only supplied in applying the ultrasonic vibration. By supplying the first purge gas, a gas flow directed to the exhaust pipe 22 from the first gas supply pipe 50 is formed within the processing container 2, and the corner portions are positioned in the midway of the gas flow. Thus, when the supplying of at least the first purge gas is maintained, the reaction product D peeled off by the ultrasonic vibration can be efficiently exhausted. In other words, when the gas flow from the upstream side to the downstream side of the corner portions can be maintained, how to supply the purge gas into the processing container 2 may be arbitrarily set. However, from the view point of evenly exhausting the inside of the processing container 2 and reducing the gas staying locations as much as possible, it is desirable to perform exhaust by providing the exhaust pipe 22 below the wafer W placed on the susceptor 10, and during the exhaust, to supply the purge gas by providing the first gas supply pipe 50 in the vicinity of the surface of the wafer W opposite to the side where the exhaust pipe 22 with the wafer W being interposed therebetween in the processing container 2, that is, at a position above the wafer W.

In addition, it is not necessary to start the applying of the ultrasonic vibration simultaneously with the supplying of the purge gas. For example, the ultrasonic vibration may be applied after starting the supplying of the purge gas.

In the foregoing exemplary embodiment, the power of the applied ultrasonic vibration is set to a range of about 20 W to about 200 W. However, when the power is excessively high, for example, the protection film of yttrium oxide sprayed within the processing container 2 may also be peeled off. Therefore, the power of the applied ultrasonic vibration may be properly set based on, for example, the kind, film thickness, and strength of the protection film within the processing container 2.

In the foregoing exemplary embodiment, the time period of applying ultrasonic vibration is set to a range of, for example, 2 sec to 20 sec. However, the contents of the present exemplary embodiment are not limited by the time period of applying ultrasonic vibration. When the time period of applying ultrasonic vibration is long, the peeling effect of the reaction product D may also be increased. However, the time required for cleaning is increased to that extent and the productivity of the plasma processing apparatus 1 is degraded. Thus, the time for applying the ultrasonic vibration may be properly set according to the required cleanliness of the inside of the processing container 2.

In addition, in stopping the applying of the ultrasonic vibration, for example, a particle monitor configured to count the number of particles (reaction product D) exhausted through the exhaust pipe 22 may be installed, for example, in the exhaust pipe 22 so that the applying of the ultrasonic vibration may be stopped when the number of particles counted per unit time, that is, the amount of particles that pass through the exhaust pipe per unit time is less than a predetermined value. In such a case, since the ultrasonic vibration is applied for a proper time period according to the situation within the processing container 2, the cleaning within the processing container 2 can be efficiently performed.

In the foregoing exemplary embodiment, the ultrasonic vibration is applied after the inside of the processing container 2 is cleaned by the plasma of cleaning gases. However, performing the cleaning by the cleaning gases may be arbitrarily set. Similarly, performing the cycle purging, which is the cleaning performed by applying a high voltage to the susceptor 10, may be arbitrary set.

In addition, in the foregoing exemplary embodiment, the supplying of the purge gases and the applying of the ultrasonic vibration are stopped after a lapse of a predetermined period time from the applying of the ultrasonic vibration (first period), and then the cycle purging is performed. However, after the supplying of the purge gases and the applying of the ultrasonic vibration are stopped, the inside of the processing container 2 may be exhausted to a predetermined vacuum degree, and then the supplying of the purge gases and the applying of the ultrasonic vibration may be performed again, or this cycle may be repeated.

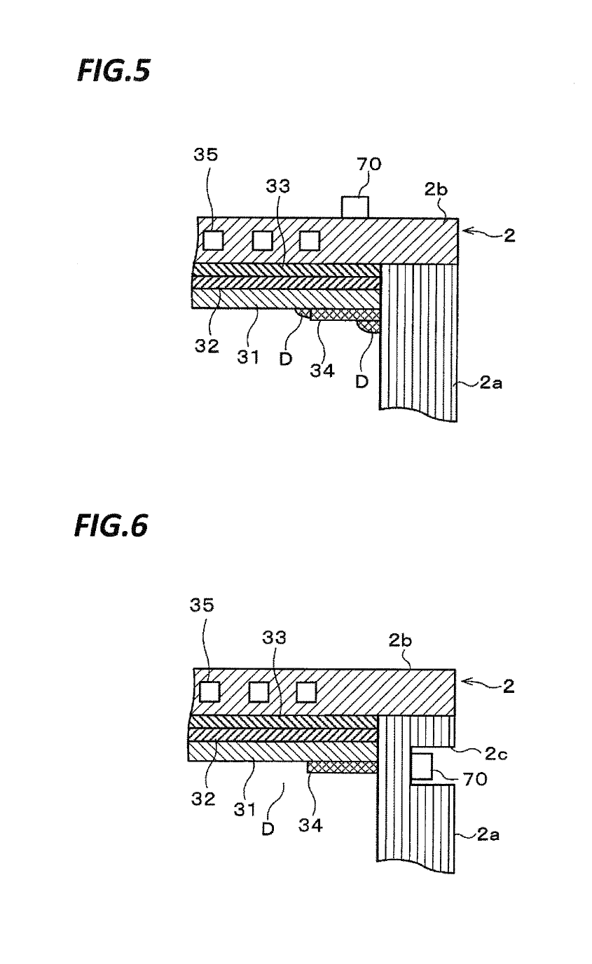

In the foregoing exemplary embodiment, a plurality of ultrasonic vibration generating mechanisms 70 are provided on the outer circumference of the processing container, for example, as illustrated in FIG. 2. However, for example, the arrangement place or the number of ultrasonic vibration generating mechanisms 70 may be arbitrarily set without being limited to the contents of the present exemplary embodiment as long as it is possible to apply ultrasonic vibration to the corner portions within the processing container 2 so as to properly peel off the reaction product D. For example, as illustrated in FIG. 5, the corresponding ultrasonic vibration generating mechanisms 70 may be provided on the top side of the cover 2b of the processing container 2 above the support member 34. Of course, the ultrasonic vibration generating mechanisms 70 may be provided both on the upper side of the processing container 2 and on the outer surface of the main body 2a.

Further, for example, as illustrated in FIG. 6, recesses 2c may be fanned to be recessed toward the center of the processing container 2 on the outer circumference of the main body 2a of the processing container 2 at a height position that is appropriately the same as that of the support member 34, and the ultrasonic vibration generating mechanisms 70 may be disposed in the recesses 2c, respectively. When the ultrasonic vibration generating mechanisms 70 are disposed in the recesses 2c such that the ultrasonic vibration applying targets and the ultrasonic vibration generating mechanisms 70 get closer to each other, the ultrasonic vibration may be efficiently applied to the targets and thus, the power of the ultrasonic vibration generating mechanisms 70 may be reduced. As a result, the costs of the ultrasonic vibration generating mechanisms 70 can be reduced, and the protection film formed within the processing container 2 can be prevented from being peeled off

In the foregoing exemplary embodiment, the plurality of ultrasonic vibration generating mechanisms 70 are simultaneously activated so as to apply ultrasonic vibration all together. However, it is possible to arbitrarily set the ultrasonic vibration applying pattern through the ultrasonic vibration generating mechanisms 70. That is, for example, it is possible to activate any of adjacent ultrasonic vibration generating mechanisms 70, and after a predetermined time period elapses, to replace ultrasonic vibration generating mechanisms 70 to be activated.

In addition, in the foregoing exemplary embodiment, the corner portions within the processing container 2 are described with the corner portion between the bottom surface of the microwave transmission plate 31 and the inner circumferential surface of the support member 34, or the corner portion between the bottom surface of the support member 34 and the inner surface of the main body 2a, by way of an example. However, the corner portions in the present exemplary embodiment are not limited to the portions formed as surfaces overlap each other, and include a recessed portion formed by, for example, the carry-in/out port 25 and the gate valve 26. Accordingly, other ultrasonic vibration generating mechanisms may be properly installed so as to apply ultrasonic vibration to the corner portion formed by the carry-in/out port 25 and the gate valve 26. In such a case, since the ultrasonic vibration generating mechanisms 70 and the other ultrasonic vibration generating mechanisms are installed in multi-stages from the upstream side toward the downstream side of the purge gas, for example, the ultrasonic vibration generating mechanisms 70 may apply ultrasonic vibration first, and then the other ultrasonic vibration generating mechanisms may sequentially apply ultrasonic vibration.

In the foregoing exemplary embodiment, descriptions have made on the cleaning method after the plasma processing by microwaves have been performed. However, the plasma processing, to which the cleaning method according to the present exemplary embodiment is applied, is not limited to the processing by microwave plasma. For example, the present disclosure may also be applied to a cleaning after a plasma processing performed by plasma generated by other means such as, for example, parallel plate plasma or ICP plasma, besides the microwave plasma.

In the foregoing exemplary embodiment, the present disclosure is applied to a plasma processing that performs a film forming processing. However, the present disclosure may also be applied to a plasma processing that performs a substrate processing such as, for example, an etching processing or sputtering, besides the film forming processing. In addition, an object to be processed by the plasma processing of the present disclosure may be any one such as, for example, a glass substrate, an organic EL substrate, or a substrate for a flat panel display (FPD).

The present disclosure is useful when performing a plasma processing on, for example, a semiconductor wafer.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A plasma processing apparatus comprising:
a processing container configured to hermetically accommodate a substrate therein;
a placement table installed on a bottom surface of the processing container, and configured to place the substrate thereon;
a gas supply mechanism configured to supply at least one of a processing gas and a purge gas to an inside of the processing container through a gas supply pipe;
a plasma generating mechanism configured to generate plasma of the processing gas within the processing container, the substrate being processed by the plasma of the processing gas;
an exhaust mechanism configured to exhaust the inside of the processing container through an exhaust pipe; and
an ultrasonic vibration generating mechanism configured to apply ultrasonic vibration to a corner portion within the processing container.

2. The plasma processing apparatus of claim 1, wherein the gas supply pipe is provided above the placement table,
the exhaust pipe is provided below the substrate placed on the placement table, and
the ultrasonic vibration generating mechanism is placed outside the processing container so as to apply the ultrasonic vibration to a corner portion between the gas supply pipe and the exhaust pipe within the processing container.

3. The plasma processing apparatus of claim 2, wherein the gas supply pipe is provided in a central portion of the processing container and above the placement table.

4. The plasma processing apparatus of claim 1, further comprising:
a controller configured: to control the plasma generating mechanism to stop plasma generation within the processing container after terminating a processing of the substrate; to control the vibration generating mechanism to apply ultrasonic vibration to the corner portion after stopping the plasma generation; and to control the gas supply mechanism to supply a purge gas to the inside of the processing container during the applying of the ultrasonic vibration.

5. The plasma processing apparatus of claim 4, wherein the controller is configured to control the gas supply mechanism and the ultrasonic vibration generating mechanism to stop the supplying of the purge gas and the applying of the ultrasonic vibration after a first predetermined time period elapses from the applying of the ultrasonic vibration, and to perform the supplying of the purge gas and the applying of the ultrasonic vibration again after a second predetermined time period elapses from the stopping of the supplying of the purge gas and the applying of the ultrasonic vibration.

6. The plasma processing apparatus of claim 5, wherein the controller is configured to control the gas supply mechanism and the ultrasonic vibration generating mechanism to repeatedly perform the supplying of the purge gas and the stopping thereof, and the applying of the ultrasonic vibration and the stopping thereof.

7. The plasma processing apparatus of claim 4, wherein the exhaust pipe is provided with a particle monitor that is configured to measure the number of particles exhausted through the exhaust pipe, and
the controller is configured to stop the applying of the ultrasonic vibration when the number of particles measured by the particle monitor per unit time is less than a predetermined value.

8. A method of cleaning an inside of a processing container in a plasma processing apparatus, the method comprising:
supplying a processing gas to the inside of the processing container to generate plasma of the processing gas so as to perform a plasma processing on a substrate placed on a placement table within the processing container, and stopping the supplying of the processing gas and the generating of the plasma after performing the plasma processing on the substrate within the processing container; and
applying ultrasonic vibration to a corner portion within the processing container and supplying a purge gas into the inside of the processing container during the applying of the ultrasonic vibration, after the substrate is carried out from the processing container.

9. The method of claim 8, wherein the supplying of the purge gas is performed through a gas supply pipe provided above the placement table,
the inside of the processing container is exhausted through an exhaust pipe provided below the substrate placed on the placement table, and
the ultrasonic vibration is applied by an ultrasonic vibration generating mechanism placed outside the processing container so as to apply the ultrasonic vibration to a corner portion between the gas supply pipe and the exhaust pipe within the processing container.

10. The method of claim 9, wherein the gas supply pipe is provided in a central portion of the processing container and above the placement table.

11. The method of claim 10, wherein the supplying of the purge gas and the applying of the ultrasonic vibration are stopped after a first predetermined time period elapses from the applying of the ultrasonic vibration, and the supplying of the purge gas and the applying of the ultrasonic vibration again are performed after a second predetermined time period elapses from the stopping of the supplying of the purge gas and the applying of the ultrasonic vibration.

12. The method of claim 11, wherein the supplying of the purge gas and the stopping thereof, and the applying of the ultrasonic vibration and the stopping thereof are repeatedly performed.

13. The method of claim 10, wherein the number of particles exhausted through the exhaust pipe is measured by a particle monitor provided in the exhaust pipe, and
the applying of the ultrasonic vibration is stopped when the number of particles measured by the particle monitor per unit time is less than a predetermined value.
